(19) United States
(12) Patent Application Publication
(10) Pub. No.: US 2013/0192659 A1
(43) Pub. Date: Aug. 1, 2013

(54) Solar Tracking System

(71) Applicants: Paul Upton, Corowa (AU); Glenn Melton, Albury (AU)

(72) Inventors: Paul Upton, Corowa (AU); Glenn Melton, Albury (AU)

(73) Assignee: UPTON ECOFORLIFE SOLAR TRACKERS PTY. LTD., Wodonga (AU)

(21) Appl. No.: 13/642,205

(22) PCT Filed: Apr. 21, 2011
(86) PCT No.: PCT/AU2011/000463

§ 371 Date: Feb. 4, 2013

(30) Foreign Application Priority Data
Apr. 27, 2010 (AU) 2010901762

(51) Int. Cl. H01L 31/052

(52) U.S. Cl. CPC H01L 31/052
USPC 136/246

(57) ABSTRACT

A solar tracking system comprising a bed rotatable about a turntable, the bed supporting at least one post structure, the post structure supporting a solar panel assembly, the solar panel assembly being pivotable to the post structure about a horizontal axis, and direct drive means to rotate the bed and pivot the solar panel assembly, whereby ball and socket linkages secure the solar panel assembly to the post structure and a lever arm coupled to the solar panel assembly through ball and socket linkages imparts drive to cause the solar panel assembly to pivot about a horizontal axis and a floating drive is positioned between the bed and the turntable so that the tracking system can absorb twisting deflections.

### INTRODUCTION

This invention relates to a solar tracking system and, in particular, relates to a drive mechanism that has the versatility to allow arrays of solar panels to be aligned with the sun during daylight hours to increase the efficiency of the solar collector.

### BACKGROUND OF THE INVENTION

Solar collectors that track the sun are well known. It is known that a solar tracker which can constantly change its direction in accordance with the position of the sun can substantially increase the overall efficiency of the collector.

Control systems for solar trackers vary from simple mechanical time driven units which track an arc of the sun across the skyline purely based on the path of the sun to other control systems that use a light sensor which point the panels at the brightest source of light at any given moment.

It is improvements in this type of solar collector that have brought about the present invention.

### SUMMARY OF THE INVENTION

According to the present invention, there is provided a solar tracking system comprising a bed rotatable about a turntable, the bed supporting at least one post structure, the post structure supporting a solar panel assembly, the solar panel assembly being pivotable to the post structure about a horizontal axis, and direct drive means to rotate the bed and pivot the solar panel assembly, whereby ball and socket linkages secure the solar panel assembly to the post structure and a lever arm coupled to the solar panel assembly through ball and socket linkages imparts drive to cause the solar panel assembly to pivot about a horizontal axis and a floating drive is positioned between the bed and the turntable so that the tracking system can absorb twisting deflections.

According to the present invention, there is provided a solar tracking system comprising a ground engaging frame supporting a turntable, a bed rotatable on the turntable, the bed supporting at least one post structure, the post structure supporting a solar panel assembly, the solar panel assembly being pivotable to the post structure about a horizontal axis, direct drive means to rotate the bed and pivot the solar panel assembly, a sun sensor to sense intensity of the sun and send signals to a controller as the intensity varies, whereby the controller causes the drive means to pivot and rotate the solar panel assembly to an optimum position under the sun.

Preferably, the drive means comprises a direct drive from an electric motor and gearbox. In a preferred embodiment, one motor drives two gearboxes to drive the solar panel support structures and a second motor and gearbox drives the turntable. Preferably, the gearboxes impart drive through a worm and wheel drive mechanism.

In a preferred embodiment, a controller sends signals to the electric motor to operate the drive. The controller may comprise an array of solar detectors each of which send electrical signals in response to the strength of the sun to the electric motor.

### DESCRIPTION OF THE DRAWINGS

An embodiment of the present invention will now be described by way of example only, in which:

FIG. 1 is a side elevational view of a solar tracking system;

FIGS. 2 and 3 is are perspective views of the solar tracking system;

FIG. 4 is a rear view of the solar tracking system;

FIG. 5 is a perspective view of part of the system illustrating the drive for tilting a solar panel support structure;

FIG. 6 is a perspective view of part of the drive of FIG. 5;

FIG. 7 is a perspective view from above of part of the solar panel supports and a turntable bed;

FIG. 8 is a partial perspective view of a drive for the turntable bed;

FIG. 9 is a partial perspective view from the underside of the turntable bed drive;

FIG. 10 is a cross sectional view through part of the turntable showing the drive to the turntable, and

FIG. 11 is a perspective view of a sun sensor which forms part of the solar tracking system.

### DESCRIPTION OF THE PREFERRED EMBODIMENT

The solar tracking system 10, as shown in the accompanying drawings, essentially comprises a base support 20 which supports a bed 30 about a turntable 25. The bed in turn supports two solar panel support structures 40, 41 that are mounted spaced apart on uprights 35, 36. The solar panel support structures 40, 41 , in use, support solar panels (not shown) and the assembly is provided with two axes of motion, namely the bed 30 can rotate about a vertical axis and each panel support 40, 41 can pivot about a horizontal axis. In this manner, the solar tracking system 10 can follow the sun and also be stored in a wind resistant position when necessary. The drawings show the tracking system but omit the solar panels which are considered well known to those in the art and are not described herein.

In a preferred embodiment, the dimensions of each solar collector support panel are 12 m×3.5 m with each solar panel being in the form of a 2 m×1 m rectangle. The system could include a single pair of uprights supporting a single array of solar panels.

The base support 20 comprises four outwardly diverging legs 11 that support a platform 12 which in turn supports the turntable 25. The bed 30 comprises a rectangular frame work 31 of steel beams with diagonal bracing struts 32 and a central support structure 33 that sits on the turntable 25. The ends of the bed 30 support the pair of upwardly extending uprights 35, 36 that support the two solar panel support structures.

The solar panel support structures 40, 41 comprise an open latticework constructed by two longitudinal, parallel beams 43, 44 supporting seven equally spaced cross beams 45.

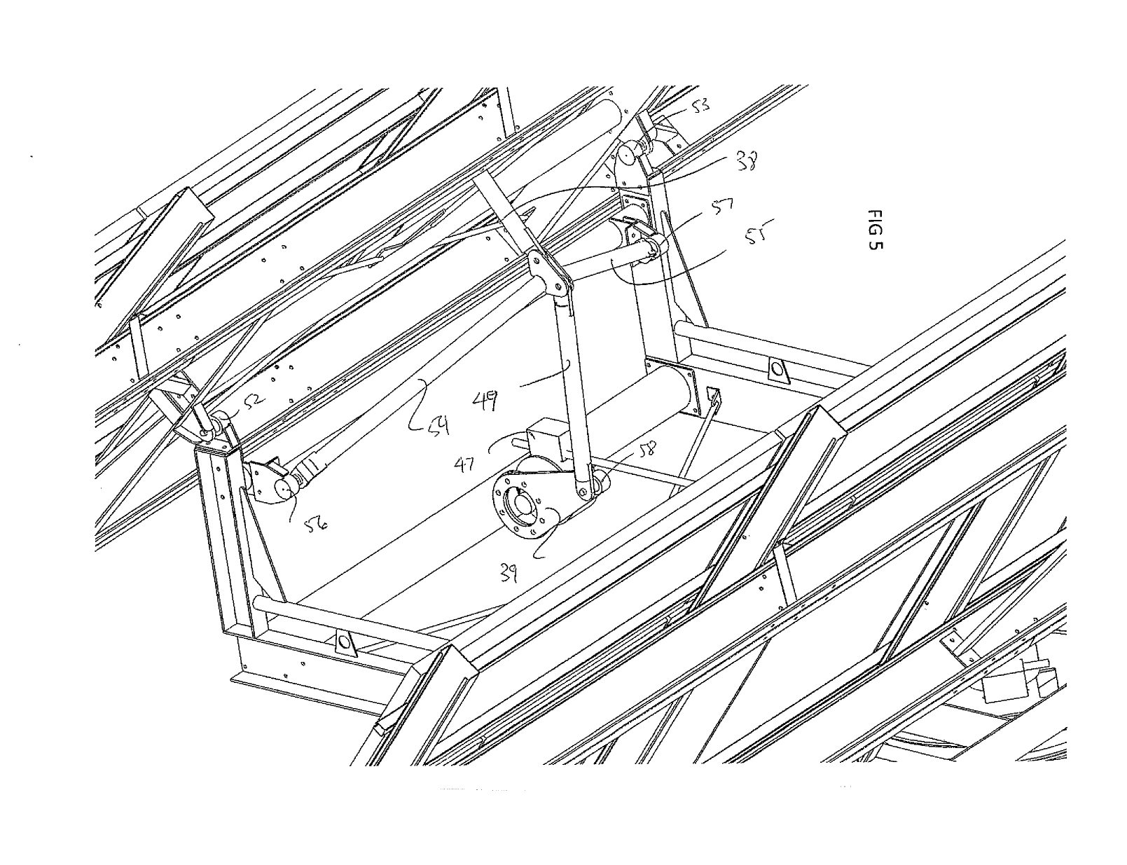

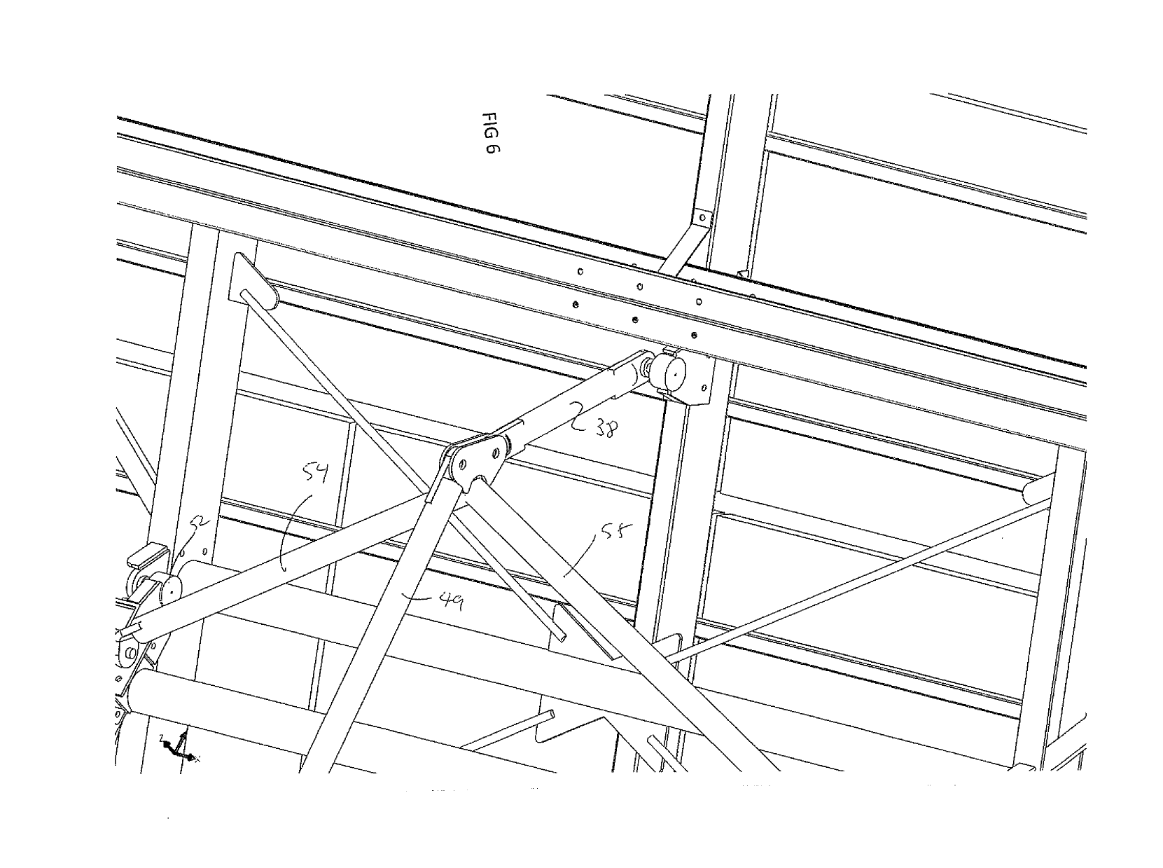

As shown in FIGS. 5 and 6, the rear of each latticework of beams 43, 44 is supported by a rectangular frame 46 which is bolted to the latticework. This frame 46 is pivotally secured across the top of the uprights 35, 36 via ball and socket joints 52, 53 shown in FIG. 5. Each upright comprises two spaced beams extending upwardly from the end of the bed 30. A pivoting linkage 38 interconnects the rear of the frame 46 with the upright beams. A vertical drive 49 is coupled to lateral linkages 54, 55 formed as a single piece and is driven by radius arm 39 in turn driven by a worm and wheel 47 mounted on the end of a drive shaft 48 that runs along the length of the bed 30. This drive and linkage provides a mechanical advantage that eliminates the backward motion caused by wind. Ball and socket joints 56, 57 join the linkages 54, 55 to the frame 46 and a ball and socket 58 connects the radial arm 39 to the vertical drive 49.

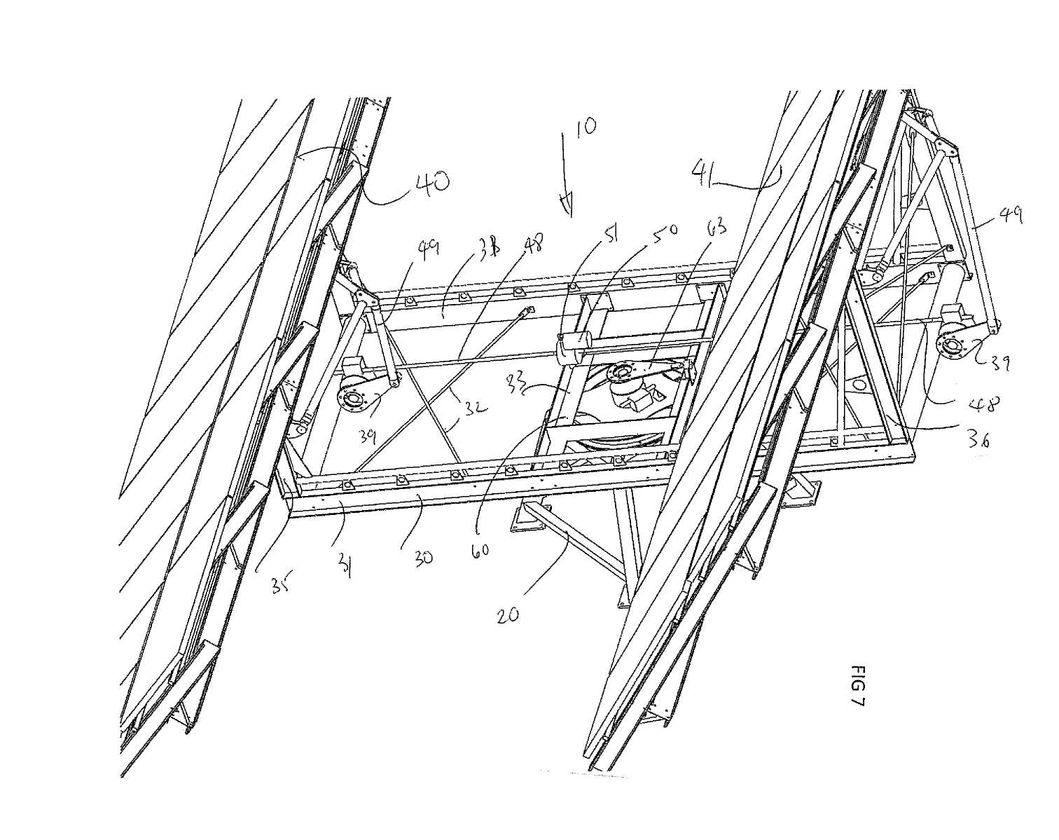

FIG. 7 illustrates a single electric motor and gearbox 50, 51 mounted internally of the bed and drive shaft 48 extending to both ends of the bed to drive radius arms 39 via worm and wheel drives 47 to effect the tilting of each solar panel support structure 40, 41. As shown in FIG. 7, the forward upright 35 has the radius arm inside the bed 30 and the rearward upright 36 has the radius arm outside the bed end.

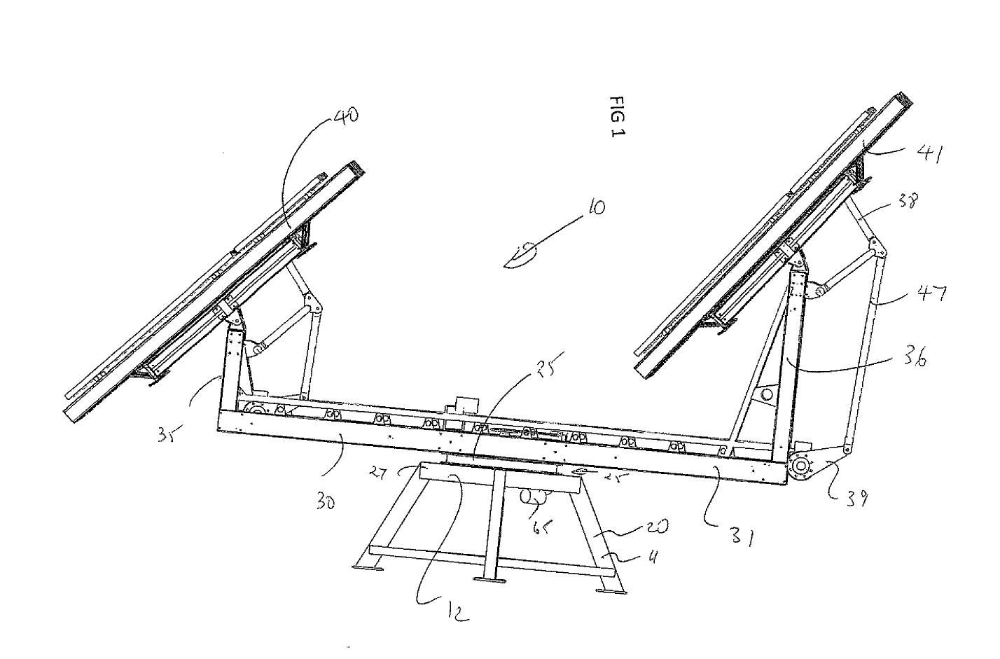

The pivoting movement of each panel is controlled between 0°, that is with the panel horizontal, and 75° off horizontal. The spacing of the support panels is defined by the dimensions of the bed 30 and the solar collectors are specifically split into two smaller arrays with one 41 placed behind the other 40 to reduce the overall effect of wind by reducing the total exposed surface area. The panels are positioned at a distance far enough apart to eliminate shading from one array onto the other. Furthermore, as shown in FIG. 1, the left hand or forward collector 40 is slightly lower than the right hand or rearward collector 41.

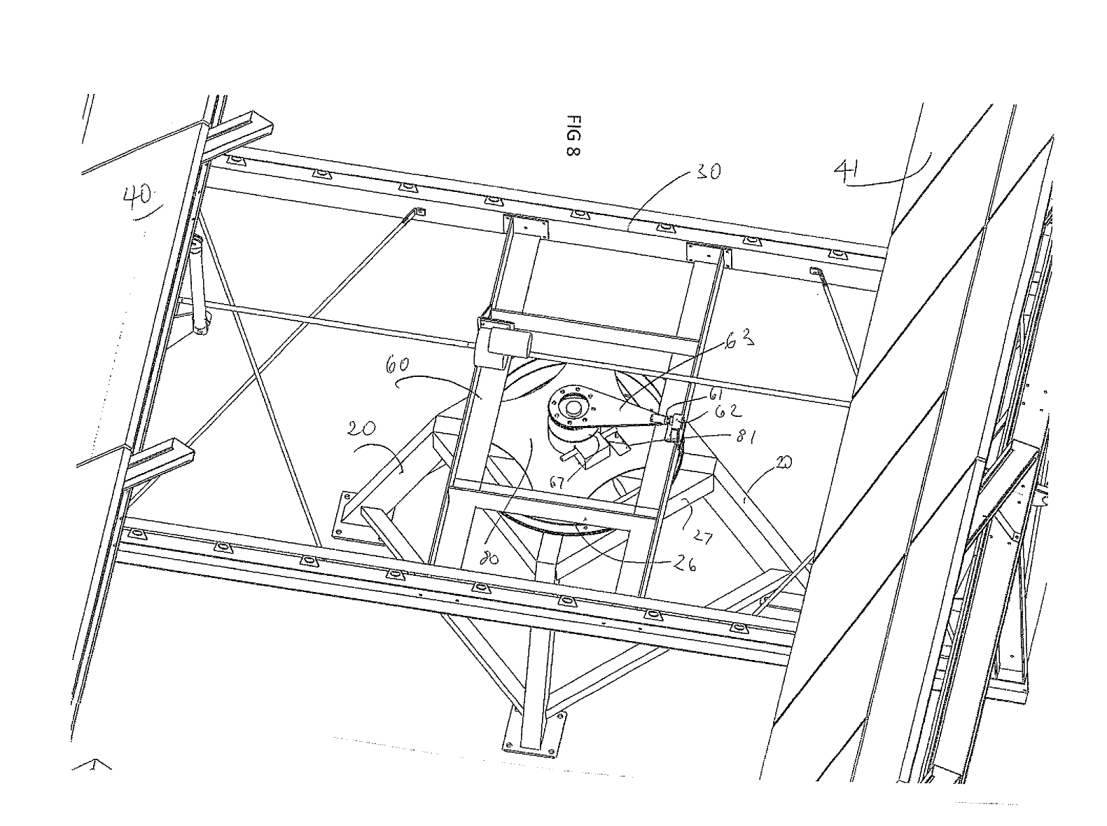

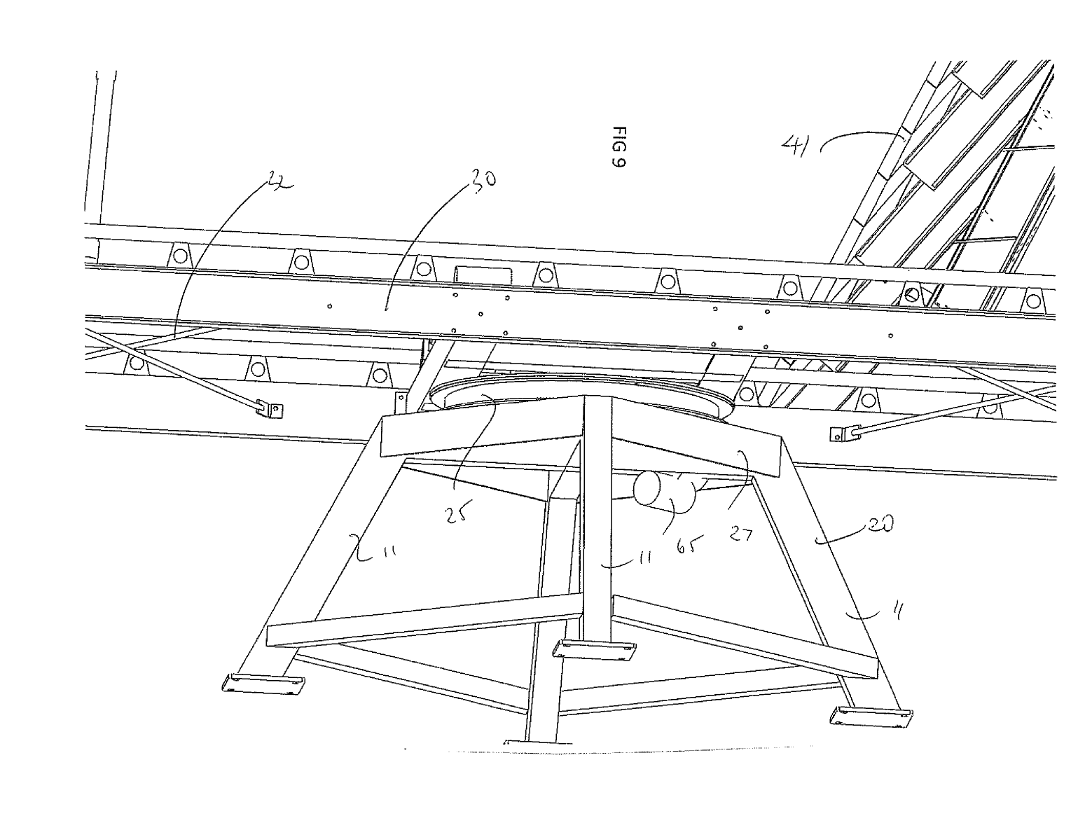

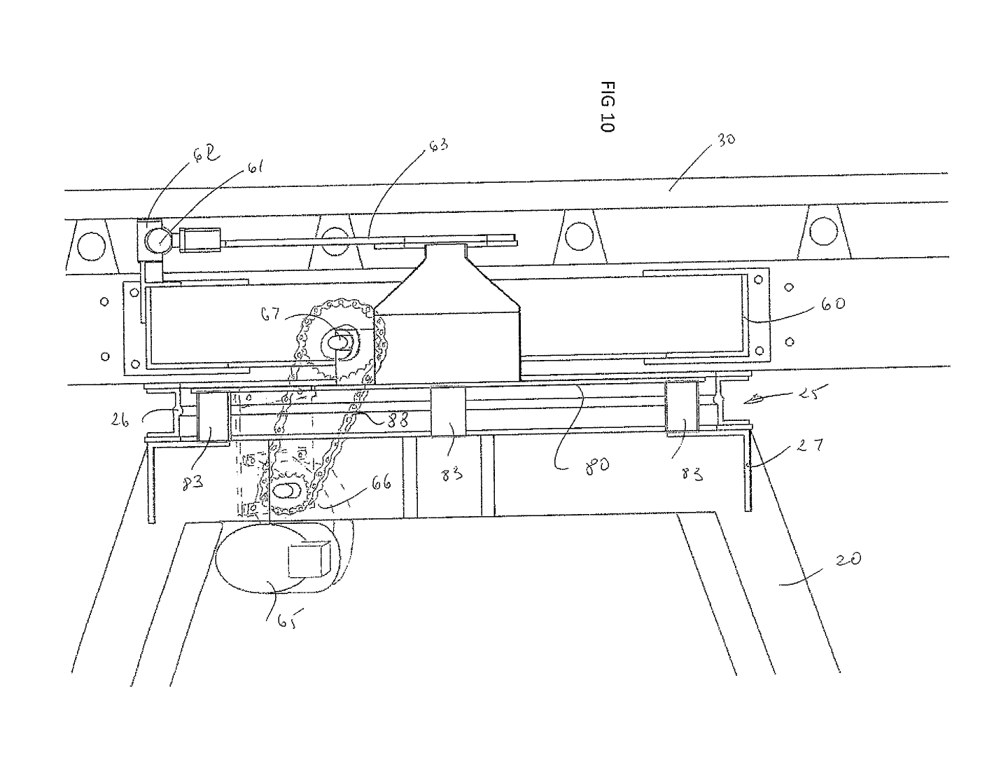

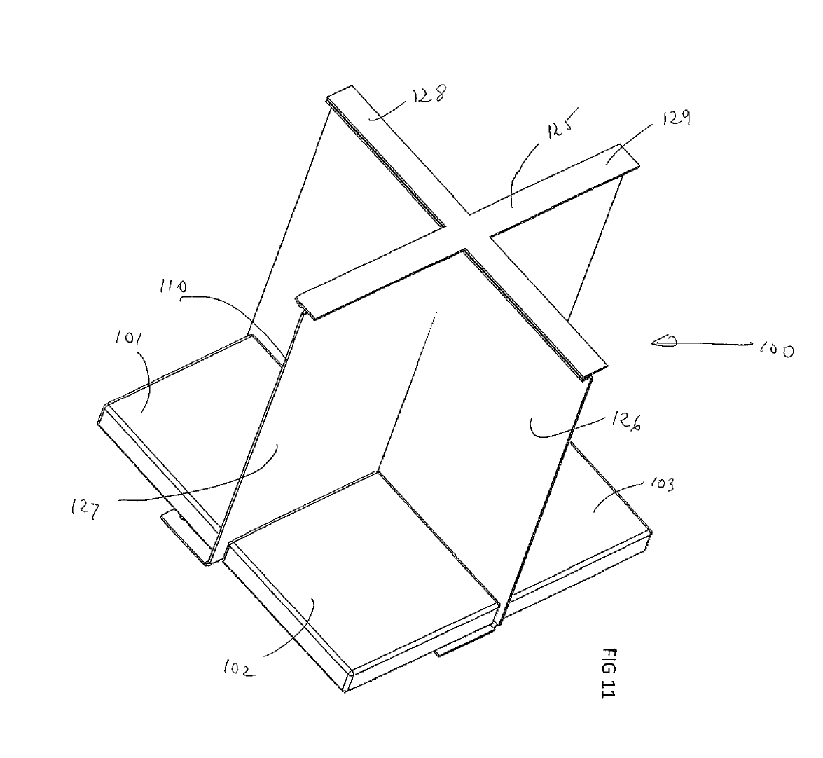

As shown in FIGS. 7 to 9, the bed 30 is mounted on the turntable 25 which includes a slew ring 26 which is free to rotate on the upper surface 27 of the base 20. The centre of the bed 30 has a rectangular frame 60 that supports a ball and socket joint 61, 62 at one side that is secured to a radius arm 63 that is, in turn, driven by the output of a worm and wheel drive 67. As shown in FIG. 10 the clover plate 80 includes a rectangular slot 81 through which a chain 88 extends connecting the worm and wheel drive 67 to an electric motor 65 an gearbox 66 which are suspended from the underside of the clover plate 80. The clover plate 80 is supported on the upper surface 27 of the base 20 by four spaced rubber torsion blocks 83. In this way the drive to the bed 30 is a floating drive that absorbs shocks, backlash and movement caused by wind forces. The electric motor and drive has the effect of causing the bed to turn about a vertical axis through the radius arm 63 rotating to drive the bed 30.

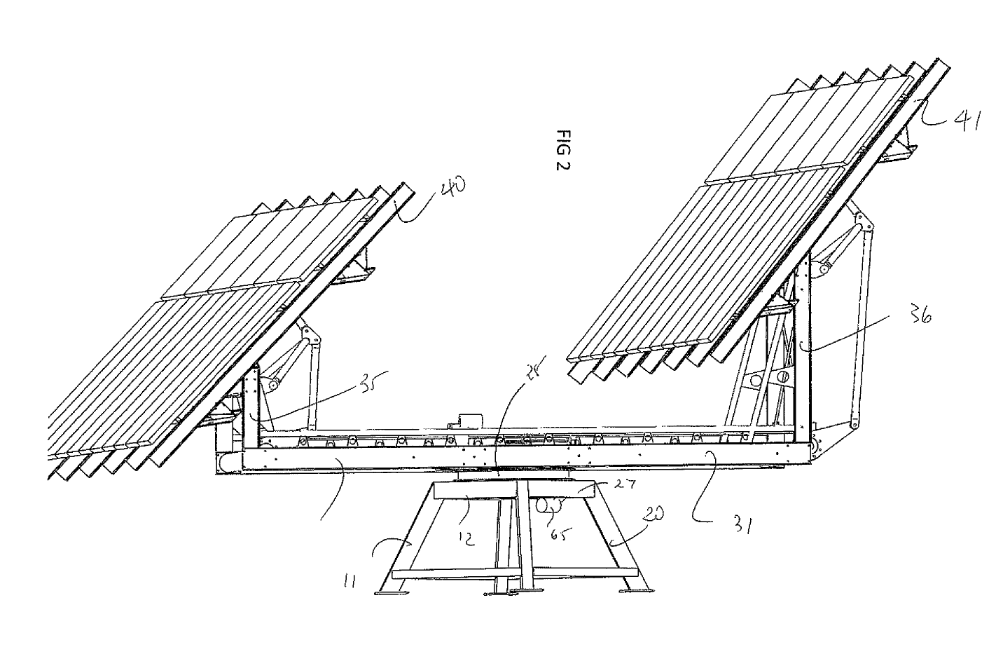

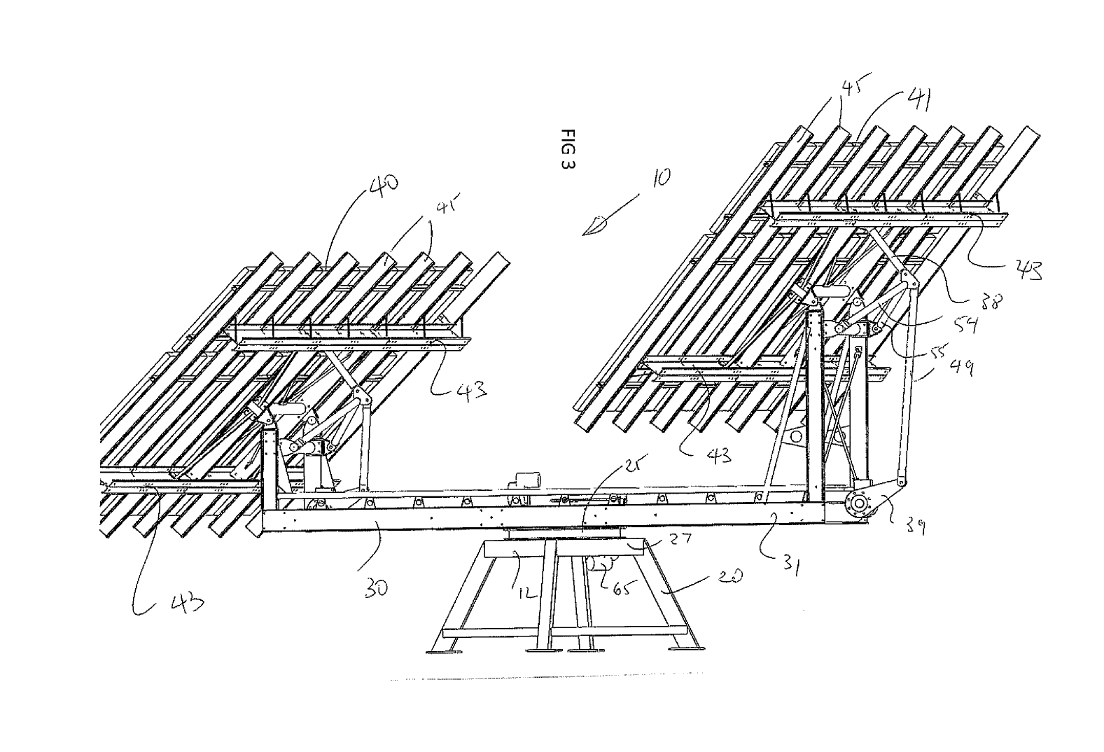

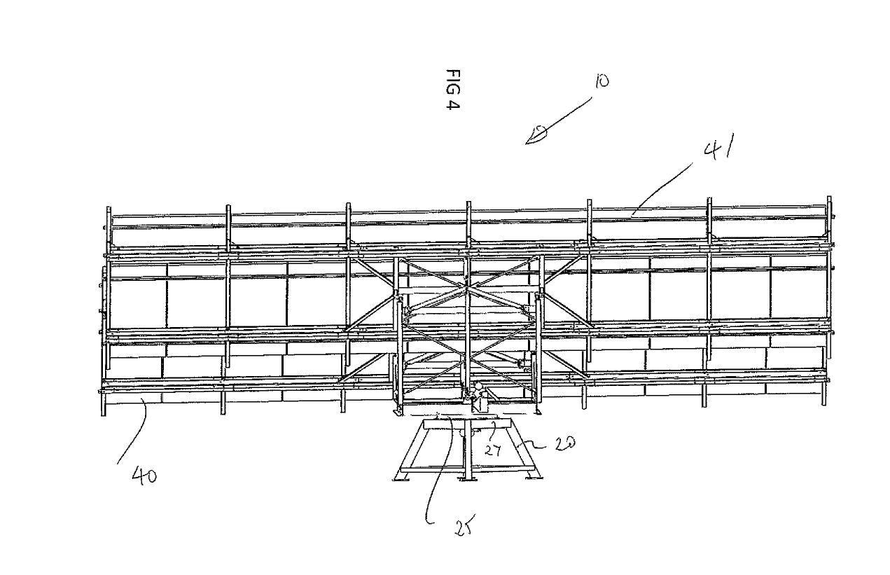

The system has been specifically designed to be heavy enough to be self-standing without the need for large concrete anchor blocks. To install the tracking system described above it is important that the ground is first leveled. Four reinforced concrete pads 600 mm×600 mm with a thickness of 75 mm are provided with a central hole. The pads are positioned to be aligned with the feet on the legs and a pin is driven through the feet and through the hole in the pads into the ground surface. In this manner the tracker is placed onto the four concrete pads. Ground screws are then turned into the ground at a 60° angle towards the tracker. The ground screws penetrate to about 1500 mm and are positioned on each side of each corner. A turnbuckle then tensions the line to the ground screw. In this manner the tracker is firmly and positively attached to the ground in a manner that it would not topple over in even the most extreme winds. The installation process is quite quick with a tracker of the kind shown in FIGS. 1 to 10 being installed within 6 hours, using conventional earth moving machines.

The system is also being designed so it is transportable.

The use of ball and socket joints allow for quick assembly and also reduce the stress on the components caused by minor misalignments. The reduction in stress also reduces the power usage. The ball and socket joints allow the system to flex and twist whilst still pivoting and turning smoothly. The direct drive through the electric motors and gearboxes provides both a mechanical advantage and a locking feature whereby when the motors are not operative the assembly is locked in position. Because drive only takes place periodically and the system is locked when the motors are not operating, the use of power is reduced.

It is understood that the system could incorporate a wind sensor so that, in extreme wind conditions, the system can be closed down by tilting the solar panels to a horizontal position to reduce the effective surface area.

The electric motors which are used to rotate the bed and tilt the solar panels are centre drive motors and gearboxes that are used in the irrigation industry to drive large centre pivot irrigators. The output of the centre motor gearbox has a 50% reduction. That output is coupled through a chain drive to a worm and wheel drive that operates on a further 50:1 ratio. The combination of the centre drive motor and gearbox and then further reduction drive through the worm and wheel means that the motor can be operated for a short period of time to rotate the bed or tilt the solar collectors through a small range of movement. This direct drive means that the motors are not always running and reduces the ultimate power usage. The motors, gearbox and worm and wheel drive are all taken from the irrigation industry and are readily available components which have a proven track record when used in hazardous outdoor conditions.

A sun sensor 100 is mounted to the tracking mechanism 10 to provide the necessary signals which are then sent via a controller to the electric motors 50, 65 to complete the rotation and tilting movements. The sun sensor 100 is mounted to the top outer edge of the highest solar panel support structure 41.

The sun sensor 100 is shown in FIG. 10 and is in the form of a rectangular base plate 120 that supports a centrally positioned standing baffle 110 comprising two cross members 126, 127. Four photovoltaic cells 101, 102, 103 of square profile are positioned in a square array around the upstanding baffle 110. The upstanding baffle terminates in a cross 125 having mutually perpendicular arms 128, 129 of width greater than the thickness of the cross members 126, 127 of the baffle 110. The cross 125 acts as a dead band control plate. Each photovoltaic cell 101-103 produces a voltage which is proportional to the intensity of the sunlight and the area of the cell that has been exposed to the sunlight. When the sun is directly in line with the central axis of the baffle 110, an equal area of each cell is exposed to an equal intensity of sunlight. Thus each cell produces the same voltage. The voltage level from the cells indicates the intensity of the sunlight. When the sun is not directly in line with the central axis of the baffle 110, a different area of each cell is exposed to an equal intensity of sunlight. Thus each cell produces a different voltage. The voltage level from the cells indicates the direction of the sunlight. The two sensors closer to the sun will receive more sunlight and produce more voltage. Thus by comparing the relative voltages from the cells, the direction of movement required to face the sun can be determined.

The voltage from each adjacent pair of cells is summed and compared to the sum of the voltages of the opposite adjacent pair. Provided a sufficient difference is detected, a signal is then sent to the controller which causes the electric motors 50, 65 to be operated for a short period (usually 2 secs) to cause the solar panels to turn and tilt to a position where higher voltages are recorded in which case the motor is stopped. When the voltages drop again a further turning and tilting action takes place. The process works in two axes at the same time and can, if necessary, be reversed. Thus if the movement is too great and the cell voltages peak and then reduce the electric motors can be reversed for a period of 1 sec to return the assembly to the correct position between the original and over corrected positions. The process works in varying sunlight intensities and, when the cells produce a very low voltage, then it is known that it is night time in which case the whole assembly returns to a startup position ready to receive the dawn sun.

The apparatus 10 also includes limit switches which limit the rotational movement of the bed and tilt of the panels. In a high wind situation (usually over 60 km/hour), a wind detector sends a signal to the controller to cause the solar panels to turn a position where there is least effect of the wind. This is usually to assume a horizontal profile. The dead band control plate 125, which is effectively the plus sign at the top of the baffle 110, controls the amount of movement which is possible without the dividers obscuring any of the cells.

This movement is known as the dead band. If the width the dead band control plate arms 128, 129 is altered, the amount of dead band allowed by the sensor can be varied. Thus the width of the arms of the baffle 110 and the height the baffle extends above the photovoltaic cells 101-103 is critical to the operation of the sensor 100.

In the preferred embodiment, the base plate 120 is 390 mm×335 mm and the baffle 110 extends to a height of 300 mm. The width of the arms 128, 129 of the dead band plate 125 is 32 mm.

In the claims which follow and in the preceding description of the invention, except where the context requires otherwise due to express language or necessary implication, the word “comprise” or variations such as “comprises” or “comprising” is used in an inclusive sense, i.e. to specify the presence of the stated features but not to preclude the presence or addition of further features in various embodiments of the invention.

1. A solar tracking system comprising a bed rotatable about a turntable, the bed supporting at least one post structure, the post structure supporting a solar panel assembly, the solar panel assembly being pivotable to the post structure about a horizontal axis, and direct drive means to rotate the bed and pivot the solar panel assembly, whereby ball and socket linkages secure the solar panel assembly to the post structure and a lever arm coupled to the solar panel assembly through ball and socket linkages imparts drive to cause the solar panel assembly to pivot about a horizontal axis and a floating drive is positioned between the bed and the turntable so that the tracking system can absorb twisting deflections.

2. A solar tracking system comprising a ground engaging frame supporting a turntable, a bed rotatable on the turntable, the bed supporting at least one post structure, the post structure supporting a solar panel assembly, the solar panel assembly being pivotable to the post structure about a horizontal axis, direct drive means to rotate the bed and pivot the solar panel assembly, a sun sensor to sense intensity of the sun and send signals to a controller as the intensity varies, whereby the controller causes the drive means to pivot and rotate the solar panel assembly to an optimum position under the sun.

3. The solar tracking assembly according to claim 2 wherein at a predetermined interval the controller sends a signal to the drive means to rotate the bed and pivot the solar panel assembly through a fixed degree of movement.

4. The solar tracking system according to claim 1 wherein the direct drive means comprises at least one electric motor and gearbox.

5. The solar tracking system according to claim 4 wherein a first electric motor and gearbox pivots the solar panel assembly relative to the post structure and a second electric motor and gearbox rotates the bed.

6. The solar tracking system according to claim 5 wherein the direct drive is imparted through a worm and wheel drive mechanism.

7. The solar tracking system according to claim 1 wherein the controller sends signals to the drive means to operate the drive means.

8. The solar tracking system according to claim 7 further including a sun sensor which sends signals to the controller, the sun sensor comprising an array of solar detectors each of which sends an electric signal in response to the strength of the sun to the controller.

9. The solar tracking system according to claim 1 wherein the lever arm provides a mechanical advantage.

10. The solar tracking system according to claim 2 further including a floating drive between the turntable and frame.

11. The solar tracking system according to claim 10 wherein an electric motor secured to the frame drives a gearbox secured to a plate mounted to the frame via flexible blocks, the output of the gearbox being connected to a drive shaft via a ball and socket joint.

12. The solar tracking system according to claim 1 wherein the bed supports two spaced pairs of post structures, each pair supporting a solar panel assembly, the spacing of the pairs and height of each solar panel assembly being sufficient to avoid one panel assembly casting a shadow on the other panel assembly.

13. The solar tracking system according to claim 12 wherein the first electric motor drives both solar panel assemblies.

14. The solar tracking system according to claim 8 wherein the sun sensor is positioned adjacent an edge of the solar panel assembly.

15. The solar tracking system according to claim 14 wherein a base plate supports a centrally positioned upstanding baffle comprising two mutually perpendicular plates forming a cross with four arms of equal length, the cross shaped baffle dividing the base plate into four sectors each supporting a photoelectric cell.

16. The solar tracking system according to claim 15 wherein each cell is coupled to a controller which sends a signal to the drive means when a sufficient voltage difference is detected between adjacent pairs of cells.

17. The solar tracking system according to claim 16 wherein a signal is sent to operate the drive means for a predetermined time.

18. The solar tracking system according to claim 17 wherein if the movement consequent to the signal causes too much movement of the solar panel assembly a reverse signal for half the predetermined time is sent to reverse the direction of movement and to compensate for the over correction.

19. The solar tracking assembly according to claim 1 wherein a ground engaging frame supports a centrally positioned slew ring defining an upper annular surface with peripherally located bearing assemblies, the bed sitting on the ring to be rotatable thereto.
